(19) United States
(12) Patent Application Publication
(10) Pub. No.: US 2017/0148889 A1
(43) Pub. Date: May 25, 2017

(54) METAL OXIDE SEMICONDUCTOR FIELD EFFECT TRANSISTOR POWER DEVICE WITH MULTI GATES CONNECTION

(71) Applicant: PFC Device Holdings Limited, Hong Kong (HK)

(72) Inventors: Kuan-Yu CHEN, New Taipei City (TW); Hsu-Heng LI, New Taipei City (TW); Mei-Ling CHEN, New Taipei City (TW)

(21) Appl. No.: 15/057,931

(22) Filed: Mar. 1, 2016

(30) Foreign Application Priority Data
Nov. 23, 2015 (TW) 104138847

(51) Int. Cl. H01L 29/49; H01L 21/28; H01L 29/06; H01L 29/78; H01L 29/66

(52) U.S. Cl. CPC H01L 29/4925; H01L 29/7831; H01L 29/66484; H01L 29/0649; H01L 21/28273

(57) ABSTRACT

A metal oxide semiconductor field effect transistor (MOSFET) power device with multi gates connection includes a first-conductive type substrate, a first-conductive type epitaxial layer arranged on the first-conductive type substrate, a plurality of device trenches defined on an upper face of the first-conductive type epitaxial layer. Each of the device trenches has, from bottom of the trench to top of the trench, a bottom gate, a split gate and a trench gate. A bottom insulating layer is formed between the bottom gate and the bottom of the trench, an intermediate insulating layer is formed between the bottom gate and the split gate, an upper insulating layer is formed between the split gate and the trench gate.

### BACKGROUND OF THE INVENTION

Field of the Invention

The present invention relates to a metal oxide semiconductor field effect transistor (MOSFET) power device, especially to a MOSFET power device with multi gates connection.

Description of Prior Art

Metal oxide semiconductor field effect transistor (MOSFET) power device is a field effect transistor with extensive applications in analog and digital circuits and is a main stream device for power device in power electronic usage. The MOSFET power device has low power dissipation due to very low conduction resistance and high input impedance. In comparison with power bipolar transistor, the MOSFET power device further has the advantage of high switching speed for its single carrier nature (no minority carrier). For now, MOSFET power devices are popular for high frequency and low voltage applications.

To further increase device density and reduce on resistance for device, MOSFET power devices with trench gate structure are important issues. However, the gate-drain charge (Qgd) increases as the device density increases; therefore and the charging-discharging speed of gate is affected. Even though split gate structure is developed to reduce gate-drain area and reduce gate-drain capacitance. The gate-drain capacitance of the MOSFET power devices still needs improvements.

### SUMMARY OF THE INVENTION

It is an object of the present invention to provide a metal oxide semiconductor field effect transistor (MOSFET) power device with reduced capacitance.

Accordingly, the present invention provides a metal oxide semiconductor field effect transistor (MOSFET) power device with multi gates connection, comprising: a first-conductive type substrate; a first-conductive type epitaxial layer arranged on the first-conductive type substrate; and a plurality of device trenches defined on an upper face of the first-conductive type epitaxial layer, each of the device trenches having, from bottom of the trench to top of the trench, a bottom gate, a split gate and a trench gate, wherein a bottom insulating layer is formed between the bottom gate and the first-conductive type epitaxial layer, an intermediate insulating layer is formed between the bottom gate and the split gate, and an upper insulating layer is formed between the split gate and the trench gate.

Accordingly, the present invention provides a method for manufacturing metal oxide semiconductor field effect transistor (MOSFET) power device with multi gates connection, comprising: providing a first-conductive type substrate and a first-conductive type epitaxial layer arranged on the first-conductive type substrate; defining a plurality of device trenches defined on an upper face of the first-conductive type epitaxial layer, each of the device trenches having, from bottom of the trench to top of the trench, a bottom gate, a split gate and a trench gate, wherein a bottom insulating layer is formed between the bottom gate and the first-conductive type epitaxial layer, an intermediate insulating layer is formed between the bottom gate and the split gate, and an upper insulating layer is formed between the split gate and the trench gate.

The gate-source area of the MOSFET power device with multi gates connection according to the present invention can be reduced because the bottom gate is electrically isolated with other elements. The capacitance and the resistance of the MOSFET power device can be reduced to enhance operation bandwidth.

### BRIEF DESCRIPTION OF DRAWING

One or more embodiments of the present disclosure are illustrated by way of example and not limitation in the figures of the accompanying drawings, in which like references indicate similar elements. These drawings are not necessarily drawn to scale.

FIGS. 1 to 9 show the sectional views for illustrating the manufacture process for the metal oxide semiconductor field effect transistor (MOSFET) power device with multi gates connection of the present invention.

### DETAILED DESCRIPTION OF THE INVENTION

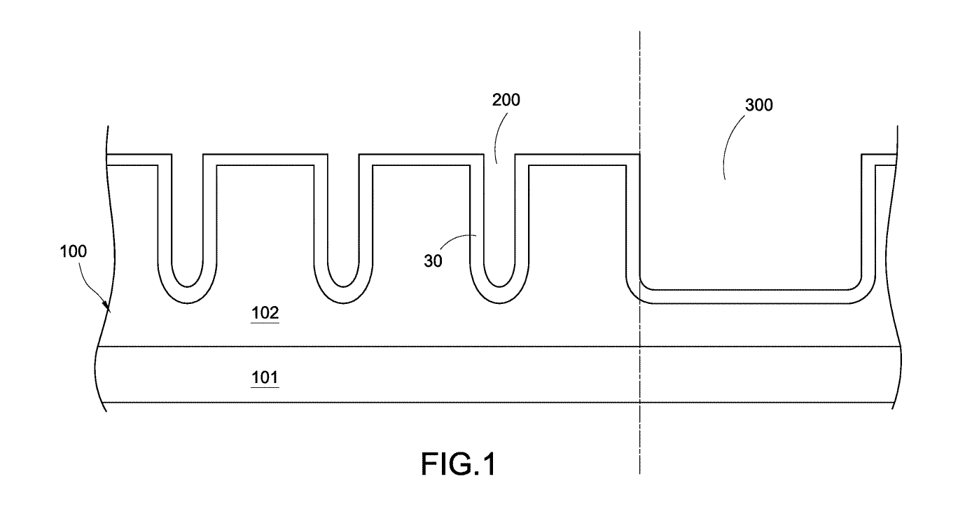

As shown in FIG. 1, a substrate structure is provided, which includes a heavily-doped N type silicon substrate 101 (N+ silicon substrate) and a lightly-doped doped N type silicon epitaxial layer 102 (N− silicon epitaxial layer). In the shown embodiment, the lightly-doped doped N type silicon epitaxial layer 102 is drawn to be thicker than the heavily-doped N type silicon substrate 101. However, in practical device, the lightly-doped doped N type silicon epitaxial layer 102 can be thinner than the heavily-doped N type silicon substrate 101 and the scope of the present invention is not limited by the shown embodiment. A plurality of photoresist patterns (not shown) are formed by using photolithography process and the photoresist patterns are used as etching masks to define a plurality of device trenches 200 and at least one termination trench 300 on the lightly-doped doped N type silicon epitaxial layer 102. The device trenches 200 on the left side of the dashed line in FIG. 1 are corresponding to the device region of the MOSFET power device and the termination trench 300 on the right side of the dashed line in FIG. 1 are corresponding to the termination region of the MOSFET power device. After the formation of the trenches 200, 300, an optional sacrificial oxidation can be performed, namely by forming a thin oxide layer and then performing an oxide etching step, the damaged surface of the trenches 200, 300 can be removed to make the sidewall of trenches 200, 300 become smooth. As also shown in FIG. 1, a thermal oxidation process is performed for the lightly-doped doped N type silicon epitaxial layer 102 formed with the trenches 200, 300 to form an oxide layer 30, which is arranged on inner wall of the trenches 200, 300 and the exposed surface of the lightly-doped doped N type silicon epitaxial layer 102. The thickness of the oxide layer 30 is, for example, 3000-6000 angstrom (Å). Moreover, the oxide layer 30 can also be formed by deposition instead of thermal oxidation.

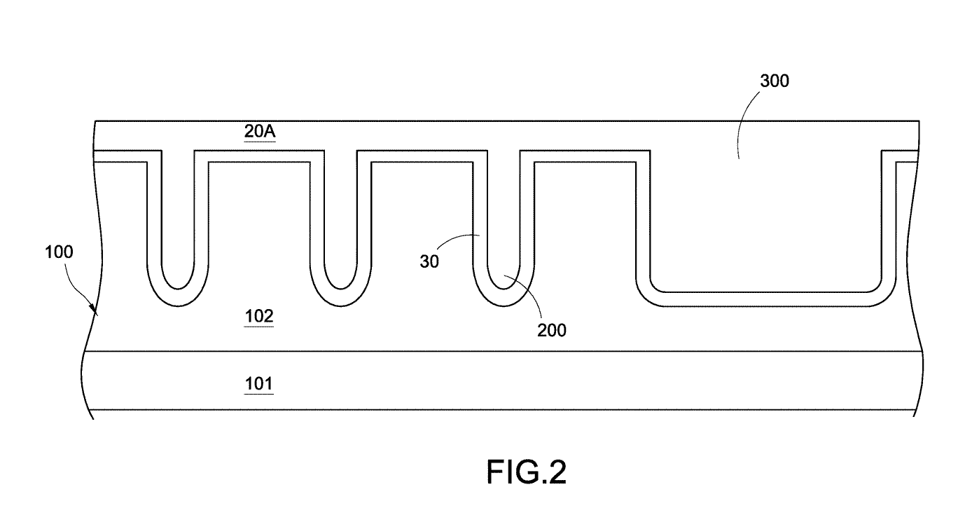

As shown in FIG. 2, a polysilicon layer 20A is formed atop the oxide layer 30 to fill the trenches 200, 300 and cover the lightly-doped doped N type silicon epitaxial layer 102. The thickness of the polysilicon layer 20A, counted from an upper face of the oxide layer 30 on the lightly-doped doped N type silicon epitaxial layer 102, is for example 1.5-2.5 um.

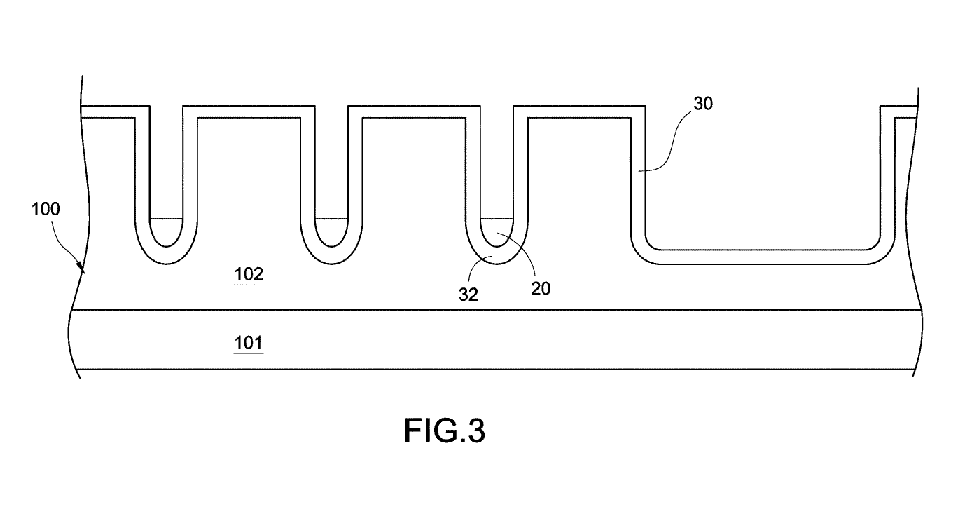

As shown in FIG. 3, after forming the polysilicon layer 20A, an etching back process (such as a dry etching process) is performed to remove part of the polysilicon layer 20A until no polysilicon layer 20A is present in termination trench 300 and part of polysilicon layer 20A is present in device trenches 200. As also shown in FIG. 3, after the etching back process, part of polysilicon layer 20A remains in device trench 200, which will be used as a bottom gate 20 in the MOSFET power device of the present invention. Moreover, the part of the oxide layer 30 between the bottom gate 20 and the N type silicon epitaxial layer 102 is a bottom insulating layer 32.

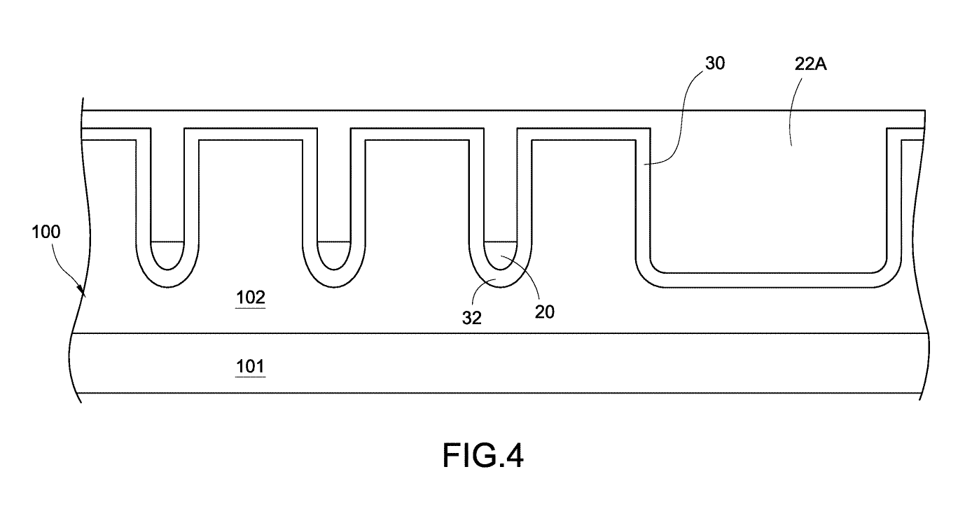

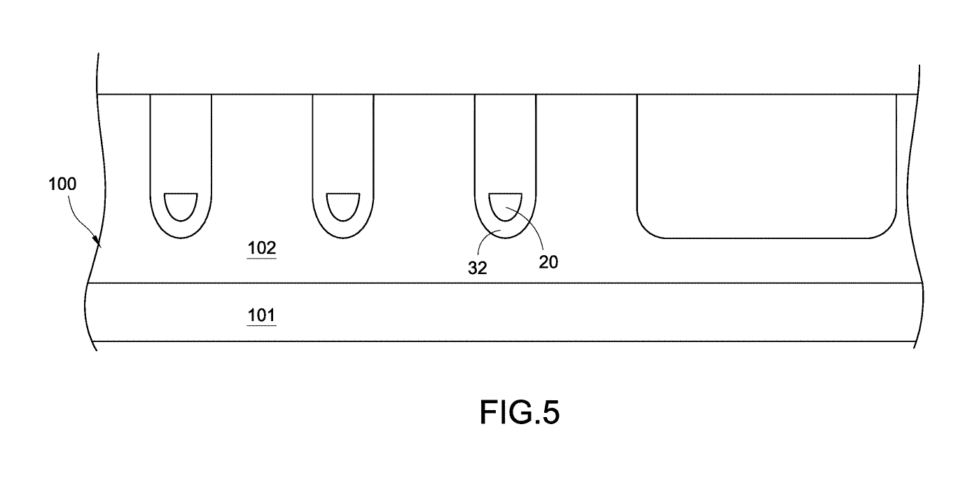

As shown in FIG. 4, an oxidation process, such as Tetraethyl Orthosilicate (LPTEOS) process or CVD process, is further conducted to form a deposited oxide layer 22A, which is formed atop the bottom gate 20 and fills the trenches 200, 300 as well as is formed atop the oxide layer 30 on the N type silicon epitaxial layer 102. The thickness of the deposited oxide layer 22A, counted from an upper face of the oxide layer 30 on the lightly-doped doped N type silicon epitaxial layer 102, is for example 1000-3000 angstrom. Moreover, as shown in FIG. 5, a CMP process is conducted to remove the part of the deposited oxide layer 22A and the part of the oxide layer 30 on the upper face of the N type silicon epitaxial layer 102 such that the followed etching step for the oxide layer can be better controlled.

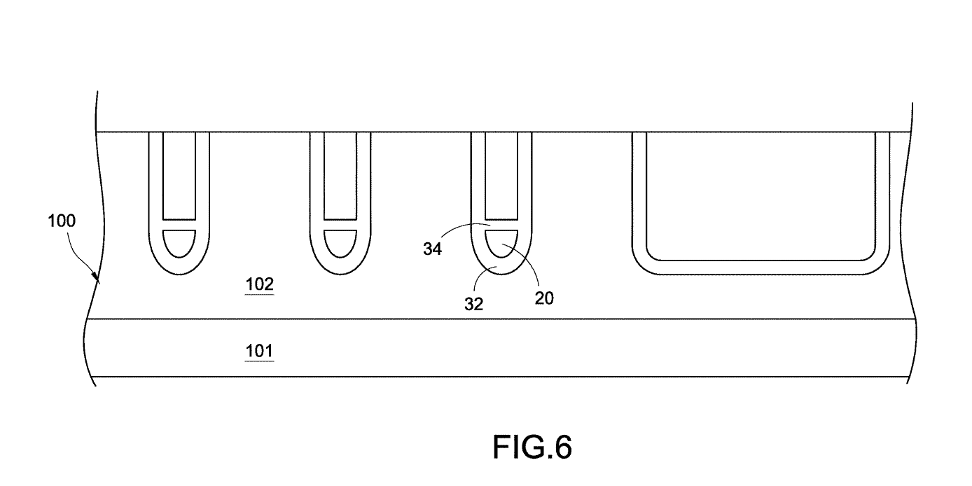

As shown in FIG. 6, a dry etching step is then performed to remove the part of the deposited oxide layer 22A in the trenches 200, 300 until a layer of oxide remains atop the bottom gate 20, which functions as an intermediate insulating layer 34 between the bottom gate 20 and a split gate (not shown) to be formed.

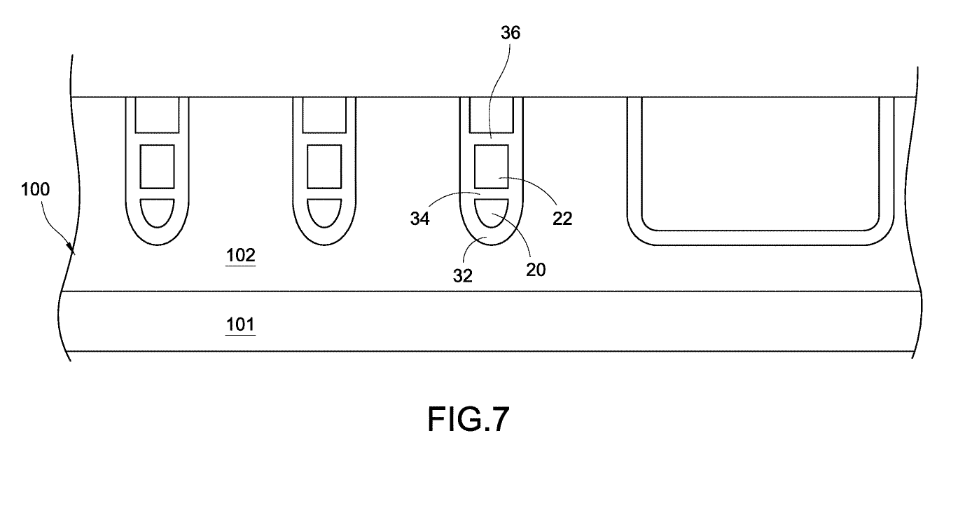

As shown in FIG. 7, steps similar to those shown in FIGS. 2-6 are performed. Namely, a polysilicon layer with thickness of 2-3 um is grown and etched back until the polysilicon layer only remains in the device trenches 200. As also shown in FIG. 7, a polysilicon layer remains atop the intermediate insulating layer 34 in the device trench 200, which will function as split gate 22. Afterward, an oxidation process, such as Tetraethyl Orthosilicate (LPTEOS) process or CVD process, is further conducted to form a deposited oxide layer (not labeled). Moreover, a CMP process is conducted to remove the part of the deposited oxide layer on the upper face of the N type silicon epitaxial layer 102, and a dry etching step is performed to remove the part of the deposited oxide layer in the trenches 200, 300 until a layer of oxide remains atop the split gate 22, which functions as an upper insulating layer 36 between the split gate 22 and a trench gate (not shown) to be formed.

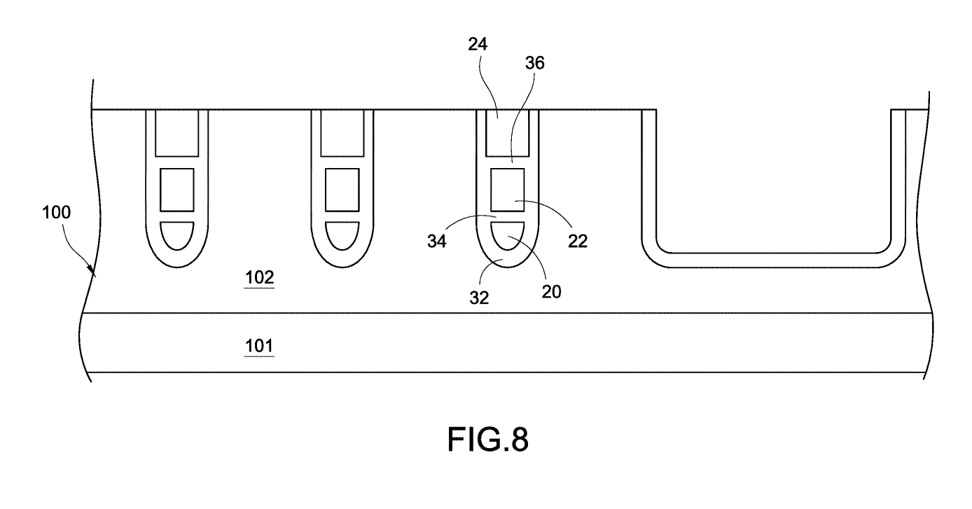

As shown in FIG. 8, a polysilicon layer with thickness of 2-3 um is grown and etched back until the polysilicon layer only remains in the device trenches 200. In FIG. 8, a remained polysilicon layer functioning as trench gate 24 is placed atop the upper insulating layer 36. Afterward, an etching back step for oxide is performed.

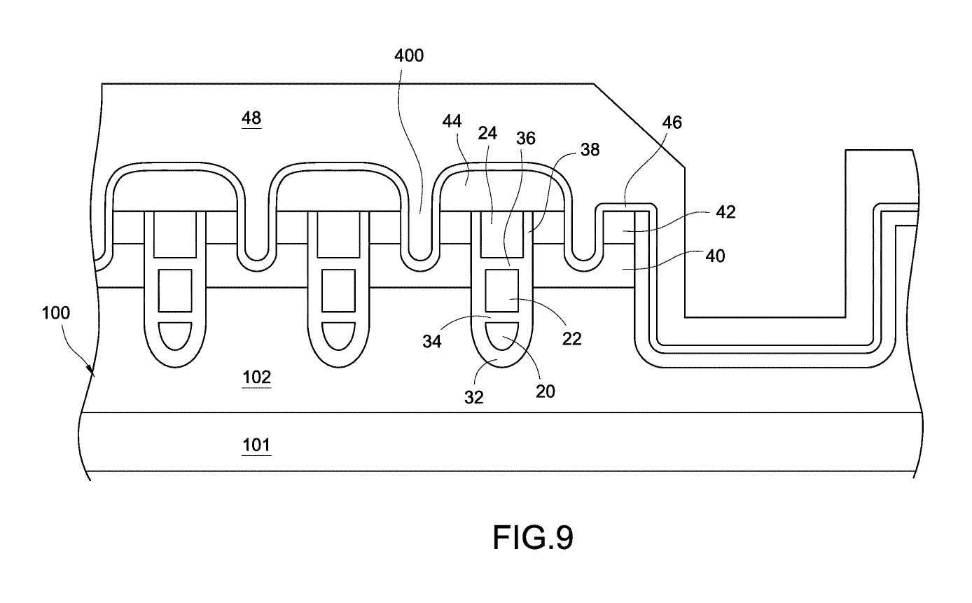

As shown in FIG. 9, after forming the trench gate 24, ion implantation and driving-in processes are performed to form P body area 40 and N type source regions 42, which are near the upper face of the N type silicon epitaxial layer 102 and outside the device trench 200. Afterward, interlayer dielectric (ILD) layer 44 is formed atop the resulting structure and then photolithography process is performed on the ILD layer to define source trench 400. Contact metal layer 46 is then formed atop the source trench 400, and the contact metal layer 46 can be Ti or TiN layer such that silicide can be formed between a later-formed metal electrode and the underlying silicon layer to reduce electrical resistance. After forming the metal contact layer 46, a metal electrode layer 48 and a passivation layer (not shown) are respectively formed.

With reference again to FIG. 9, this figure also shows a sectional view of the MOSFET power device with multi gates connection of the present invention. The MOSFET power device comprises an N type substrate structure 100 (including a heavily-doped N type silicon substrate 101 and a lightly-doped doped N type silicon epitaxial layer 102), a plurality of device trenches 200 in the device region, and at least one termination trench 300 in the termination region. Moreover, the MOSFET power device further comprises, in each device trench 200 and from the bottom to the top of the trench, a bottom gate 20, a split gate 22 and a trench gate 24, where a bottom insulating layer 32 is placed between the bottom gate 20 and the lightly-doped doped N type silicon epitaxial layer 102, an intermediate insulating layer 34 is placed between the bottom gate 20 and the split gate 22, and an upper insulating layer 36 is placed between the split gate 22 and the trench gate 24. Moreover, the MOSFET power device further comprises a P body area 40 and N type source regions 42, which are near the upper face of the N type silicon epitaxial layer 102 and outside the device trench 200. The N type source regions 42 are placed within the P body area 40. Moreover, the MOSFET power device further comprises gate oxide layer 38 between the trench gate 24 in the device trench 200 and the N type source region 42 outside the device trench 200. Moreover, the MOSFET power device further comprises source trenches 400, each between the adjacent device trenches 200 and ILD layer 44 beside the source trench 400 and atop the trench gate 24 and the N type source regions 42. The MOSFET power device further comprises a metal contact layer 46 on inner wall of the source trench 400 and atop the ILD layer 44, and comprises a metal electrode layer 48 atop the metal contact layer 46 to function as source electrode.

In the MOSFET power device shown in FIG. 9, the trench gate 24 electrically connects with gate electrode (not shown) to obtain operation voltage, and the split gate 22 electrically connects with the N type source regions 42 through buried-in electrode (not shown). Moreover, the bottom gate 20 is electrically isolated with the split gate 22 through the intermediate insulating layer 34 therebetween and is not electrically connected with other elements of the MOSFET power device. By the provision of the bottom gate 20, the gate-drain area can be further reduced such that the equivalent capacitance and equivalent resistance of the MOSFET power device can be further reduced to enhance the operation bandwidth.

The person skilled in the art can know other implementations are also feasible for above-mentioned embodiment. For example, the N type substrate structure 100 can be replaced with P type substrate structure, and correspondingly the N type source regions 42 are replaced with P type source regions, and the P body area 40 is replaced with N body area.

Thus, particular embodiments have been described. Other embodiments are within the scope of the following claims. For example, the actions recited in the claims may be performed in a different order and still achieve desirable results.

What is claimed is:

1. A metal oxide semiconductor field effect transistor (MOSFET) power device with multi gates connection, comprising:
a first-conductive type substrate;
a first-conductive type epitaxial layer arranged on the first-conductive type substrate; and
a plurality of device trenches defined on an upper face of the first-conductive type epitaxial layer, each of the device trenches having, from bottom of the trench to top of the trench, a bottom gate, a split gate and a trench gate,
wherein a bottom insulating layer is formed between the bottom gate and the first-conductive type epitaxial layer, an intermediate insulating layer is formed between the bottom gate and the split gate, and an upper insulating layer is formed between the split gate and the trench gate.

2. The MOSFET power device in claim 1, wherein the bottom gate, the split gate and the trench gate are made of polysilicon.

3. The MOSFET power device in claim 1, wherein the bottom gate is electrically isolated with the split gate and the trench gate.

4. The MOSFET power device in claim 1, wherein the bottom gate is thermal oxide or deposited oxide.

5. The MOSFET power device in claim 1, wherein the intermediate insulating layer and the upper insulating layer are deposited oxide.

6. The MOSFET power device in claim 1, further comprising a second conductive type body area outside the device trench and a first conductive type source region at upper portion of the second conductive type body area.

7. The MOSFET power device in claim 1, wherein the first conductive type is N type or P type.

8. The MOSFET power device in claim 6, further comprising:
an interlayer dielectric (ILD) layer arranged atop the trench gate and the first conductive type source region; and
a contact metal layer arranged atop the ILD layer.

9. A method for manufacturing metal oxide semiconductor field effect transistor (MOSFET) power device with multi gates connection, comprising:
providing a first-conductive type substrate and a first-conductive type epitaxial layer arranged on the first-conductive type substrate;
defining a plurality of device trenches defined on an upper face of the first-conductive type epitaxial layer, each of the device trenches having, from bottom of the trench to top of the trench, a bottom gate, a split gate and a trench gate,
wherein a bottom insulating layer is formed between the bottom gate and the first-conductive type epitaxial layer, an intermediate insulating layer is formed between the bottom gate and the split gate, and an upper insulating layer is formed between the split gate and the trench gate.

10. The method in claim 9, wherein the bottom gate, the split gate and the trench gate are made of polysilicon.

11. The method in claim 9, wherein the bottom gate is electrically isolated with the split gate and the trench gate.

12. The method in claim 9, wherein the bottom gate is thermal oxide or deposited oxide.

13. The method in claim 9, wherein the intermediate insulating layer and the upper insulating layer are deposited oxide.

14. The method in claim 9, further comprising:
forming a second conductive type body area outside the device trench, and forming a first conductive type source region at upper portion of the second conductive type body area

15. The method in claim 9, wherein the first conductive type is N type or P type.

16. The method in claim 9, further comprising:
forming an interlayer dielectric (ILD) layer arranged atop the trench gate and the first conductive type source region; and
forming a contact metal layer arranged atop the ILD layer.
